(19) United States
(12) Patent Application Publication
(10) Pub. No.: US 2025/0254813 A1
(43) Pub. Date: Aug. 7, 2025

(54) EJECTOR

(71) Applicant: Southco Manufacturing and Technology (Shenzhen) Co., Ltd., Bao An District (CN)

(72) Inventors: Hung-Yuan HUANG, New Taipei City (TW); Bing-Hua CHIANG, Hualien County (TW); Lei CAI, Shanghai (CN)

(73) Assignee: Southco Manufacturing and Technology (Shenzhen) Co., Ltd., Bao An District (CN)

(21) Appl. No.: 19/044,782

(22) Filed: Feb. 4, 2025

(30) Foreign Application Priority Data
Feb. 5, 2024 (CN) 202410166272.2

(51) Int. Cl. H05K 7/14

(52) U.S. Cl. CPC H05K 7/1401; H05K 7/1485

(57) ABSTRACT

The present disclosure discloses an ejector including a housing; a handle pivotally connected to the housing around a first pivot axis and having a first pivot position and a second pivot position; and a button pivotally connected to the housing around a second pivot axis and having a locking position and an unlocking position, wherein the handle is locked by the button when the button is in the locking position and the handle is in the first pivot position, wherein the first fixing element prevents the housing from moving in a first direction relative to the object and allows the housing to move in a second direction relative to the object, and the second fixing element prevents the housing from moving in the first direction and the second direction relative to the object. The ejector provided by the present disclosure is simple in structure and convenient to install.

### CROSS-REFERENCE TO RELATED APPLICATIONS

This application is based upon and claims priority to Chinese Patent Application No. 202410166272.2, filed on Feb. 5, 2024, and entitled “EJECTOR”, the entire contents thereof are incorporated herein by reference.

### TECHNICAL FIELD

The present disclosure relates to an ejector, in particular to an ejector for inserting an object into a bracket or pulling the object out of the bracket.

### BACKGROUND

An ejector is a device that helps a user insert a first object into a second object or pull the first object out of the second object.

One such application is a server. A server bracket is a device for placing and fixing one or more servers. In some cases, it is necessary to lock or unlock a storage device to or from the server through an ejector. On the other hand, because an engagement between the storage device and the server is tight, a large force is needed to insert or pull the storage device into or out of the server, and at the same time, the storage device usually has an elongate shape and is inserted into the server, so it is not conducive for the user to grasp the storage device. Therefore, it is necessary to insert the storage device into the server or pull the storage device out from the server with the help of the ejector.

In other cases, it is necessary for the ejector to have a better heat dissipation function. In this way, a higher standard is required for the design of the ejector.

The installation process of the existing ejector is complicated, and the structure of the parts of the ejector is also complicated.

Therefore, there is a need for an ejector that is simple to install, reliable in structure and easy to manufacture.

### SUMMARY

A purpose of the present disclosure is to provide an ejector which can be conveniently installed on an object.

A purpose of the present disclosure is to provide an ejector which is convenient to operate, reliable in structure and low in manufacturing cost.

In order to achieve the above purpose, the present disclosure provides an ejector, which is fixed to an object and includes: a housing fixed to the object by means of a first fixing element and a second fixing element; a handle pivotally connected to the housing around a first pivot axis and having a first pivot position and a second pivot position; a button pivotally connected to the housing around a second pivot axis and having a locking position and an unlocking position, where the handle is locked by the button when the button is in the locking position and the handle is in the first pivot position, where the first fixing element prevents the housing from moving in a first direction relative to the object and allows the housing to move in a second direction relative to the object, and the second fixing element prevents the housing from moving in the first direction and the second direction relative to the object.

In one embodiment, the first direction is perpendicular to the second direction.

In one embodiment, the housing includes a positioning portion formed as a U-shaped fork, and any one of the first fixing element and the second fixing element is one of a screw, a bolt, a rivet and a rivet post, and the first fixing element is engaged with the positioning portion to prevent the housing from moving in the first direction relative to the object.

In one embodiment, the handle includes a button engaging portion, an insertion abutting portion and a pull-out abutting portion, where the button locks the handle by abutting against the button engaging portion, a distance from the button engaging portion to the first pivot axis is greater than a distance from the insertion abutting portion to the first pivot axis, and the distance from the button engaging portion to the first pivot axis is greater than a distance from the pull-out abutting portion to the first pivot axis.

In one embodiment, the ejector is installed to a bracket, when the handle is rotated from the first pivot position to the second pivot position, the pull-out abutting portion abuts against a part of the bracket to at least partially pull out the object from the bracket, and when the handle is rotated from the second pivot position to the first pivot position, the inserting abutting portion abuts against the part of the bracket to fix the object to the bracket.

In one embodiment, the ejector includes a first elastic element and a second elastic element, where the first elastic element is provided between the housing and the handle to apply a force towards the second pivot position to the handle, and the second elastic element is provided between the housing and the button to apply a force towards the locking position to the button.

In one embodiment, the ejector further includes a light guide element, and the housing includes a channel extending along the first direction, and the light guide element is provided in the channel.

In one embodiment, the ejector further includes a cover plate, one end of the channel blocks the light guide element, and the other end of the channel is open, and the cover plate covers the other end that is open of the channel to block the light guide element.

In one embodiment, the one end of the channel has a first hole, and the cover plate has a second hole, where both the first hole and the second hole are aligned with the light guide element, and each of a size of the first hole and a size of the second hole is smaller than a size of the light guide element.

In one embodiment, the light guide element is an optical fiber, the optical fiber is straight, and the cover plate is translucent.

In one embodiment, the handle has a through hole, and the first hole is exposed through the through hole when the handle is in the first pivot position.

In one embodiment, the ejector includes an electromagnetic shielding element, and the electromagnetic shielding element contacts the object and the bracket and extends out of the housing.

In one embodiment, the electromagnetic shielding element has a contact arm, and the contact arm is elastically connected to the bracket.

In one embodiment, the electromagnetic shielding element has a contact hole, and a plurality of contact protrusions extending to a center of the contact hole are formed in the contact hole, and the second fixing element passes through the contact hole and the plurality of contact protrusions contact the second fixing element.

In one embodiment, the housing has a first concave portion and a second concave portion, the second fixing element extends from the first concave portion to the second concave portion, and the electromagnetic shielding element is partially located in the second concave portion.

In one embodiment, the electromagnetic shielding element is located at both sides of the housing.

In one embodiment, the electromagnetic shielding element has a plurality of contact arms extending along the second direction.

In one embodiment, the ejector includes an extension portion, where the extension portion is integrally formed with the housing and extends laterally from the housing, and the front surface of the extension portion has a plurality of holes arranged in a plurality of array.

In one embodiment, the handle has a convex rib, and the convex rib protrudes towards the housing in the first direction and extends in a third direction perpendicular to the first direction and the second direction.

In one embodiment, the handle has a first inclined plane and the button has a second inclined plane, and the first inclined plane abuts against the second inclined plane to push the button from the locking position to the unlocking position during a rotation of the handle from the second pivot position to the first pivot position.

In one embodiment, both sides of the button are respectively provided with an elastic arm and a pivot portion arranged at an end of the elastic arm, and the button is pivotally connected to the housing by means of the elastic arm and the pivot portion.

The ejector provided by the present disclosure has reliable structure, simple operation and low manufacturing cost.

The ejector provided by the present disclosure can be conveniently installed on an object.

### BRIEF DESCRIPTION OF THE DRAWINGS

Various objects, features and advantages of the present disclosure will become more apparent by considering the following detailed description of preferred embodiments of the present disclosure in conjunction with the accompanying drawings. The drawings are only exemplary illustrations of the present disclosure and are not necessarily drawn to scale. In the drawings, the same reference numerals refer to the same or similar parts throughout. In the drawings:

FIGS. 1A-IF are a front view, a plan view, a left view, a right view, a top view and a bottom view, respectively, of an ejector and an object according to a first embodiment of the present disclosure;

FIGS. 1G-1J are perspective views from different angles of the ejector according to the first embodiment of the present disclosure, respectively;

FIG. 2 is an exploded perspective view of the ejector according to the first embodiment of the present disclosure;

FIG. 3 is a perspective view of the ejector and the object according to the first embodiment of the present disclosure, in which the ejector is being installed on the object;

FIG. 4A is a perspective view of the ejector and the object according to the first embodiment of the present disclosure, in which a button is in a locking position;

FIG. 4B is a perspective view of the ejector and the object according to the first embodiment of the present disclosure, in which the button is in an unlocking position;

FIG. 5 is a perspective view of the ejector and the object according to the first embodiment of the present disclosure, in which the handle is rotated away from a housing of the ejector;

FIG. 6A is a top view of the ejector and the object according to the first embodiment of the present disclosure, in which the ejector is being installed on the object;

FIG. 6B is a cross-sectional view taken along a line A-A of FIG. 6A;

FIG. 7A is a top view of the ejector and the object according to the first embodiment of the present disclosure, in which the button is in the locking position;

FIG. 7B is a cross-sectional view taken along a line B-B of FIG. 7A;

FIG. 8A is a top view of the ejector and the object according to the first embodiment of the present disclosure, in which the button is in the unlocking position;

FIG. 8B is a cross-sectional view taken along a line C-C of FIG. 8A;

FIG. 9A is a top view of the ejector and the object according to the first embodiment of the present disclosure, in which the handle is rotated away from the housing of the ejector;

FIG. 9B is a cross-sectional view taken along a line D-D of FIG. 9A;

FIG. 10 is a partially exploded perspective view of the ejector according to the first embodiment of the present disclosure;

FIG. 11 is another partial exploded perspective view of the ejector according to the first embodiment of the present disclosure;

FIGS. 12A-12F are a front view, a plan view, a left view, a right view, atop view and a bottom view, respectively, of an ejector and an object according to a second embodiment of the present disclosure;

FIGS. 12G-12J are perspective views from different angles of the ejector according to the second embodiment of the present disclosure, respectively;

FIG. 13 is an exploded perspective view of the ejector according to the second embodiment of the present disclosure;

FIGS. 14A-14F are a front view, a plan view, a left view, a right view, a top view and a bottom view, respectively, of an ejector and an object according to a third embodiment of the present disclosure;

FIGS. 14G-14H are perspective views from different angles of the ejector according to the third embodiment of the present disclosure, respectively;

FIG. 15 is an exploded perspective view of the ejector according to the third embodiment of the present disclosure;

FIG. 16A is a perspective view of the ejector and the object according to the third embodiment of the present disclosure, in which the button is in the locking position;

FIG. 16B is a perspective view of the ejector and the object according to the third embodiment of the present disclosure, in which the button is in the unlocking position;

FIG. 16C is a perspective view of the ejector and the object according to the third embodiment of the present disclosure, in which the handle is rotated away from the housing of the ejector;

FIG. 17A is a perspective view of the ejector and the object according to the third embodiment of the present disclosure, in which a part of the housing is removed to show an internal structure and the button is in the locking position;

FIG. 17B is a perspective view of the ejector and the object according to the third embodiment of the present disclosure, in which a part of the housing is removed to show the internal structure and the button is in the unlocking position; and

FIG. 17C is a perspective view of the ejector and the object according to the third embodiment of the present disclosure, in which a part of the housing is removed to show the internal structure and the handle is rotated away from the housing of the ejector.

### LIST OF REFERENCE NUMERALS

100 ejector
   110 housing
      111 side wall
         1111 shaft hole
      112 head
         1121 first concave portion
      113 channel
      114 positioning portion
      115 extension portion
         1151 heat emission hole
      116 first hole
      117 second concave portion
   120 handle
      121 through hole
      122 button engaging portion
      123 handle shaft installing portion
      124 insertion abutting portion
      125 pull-out abutting portion
      126 convex rib
      127 first inclined plane
   130 button
      131 handle clamping portion
      132 button shaft installing portion
      133 button elastic element abutting portion
      134 anti-slip portion
      135 second inclined plane
      136 elastic arm
      137 pivot portion
   140 cover plate
      141 second hole
   150 electromagnetic shielding element
      151 contact arm
      152 contact hole
      153 contact projection
      154 wing portion
   161 first elastic element
   162 second elastic element
   163 handle shaft
   164 button shaft
   165 light guide element
   166 first fixing element
      1661 clamped portion
   167 second fixing element
400 object
   410 fixing hole
   420 light emitting portion

### DETAILED DESCRIPTION

In order to further illustrate the principle and structure of the present disclosure, the preferred embodiments of the present disclosure will be described in detail with the attached drawings. However, the embodiments are only for illustration and explanation, and cannot be used to limit the patent protection scope of the present disclosure.

The term used in the present disclosure is for the purpose of describing specific embodiments only and is not intended to limit the present disclosure. The singular forms “a”, “an”, “said” and “the” used in the present disclosure and the appended claims are also intended to include the plural forms, unless the context clearly indicates other meaning. It should also be understood that the term “and/or” as used herein refers to and includes any or all possible combinations of one or more associated listed items.

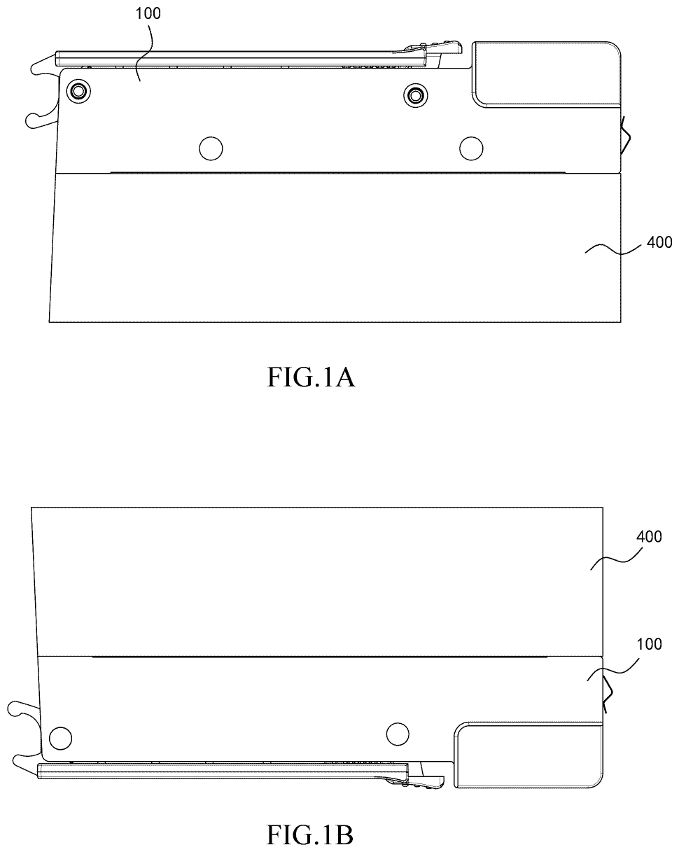

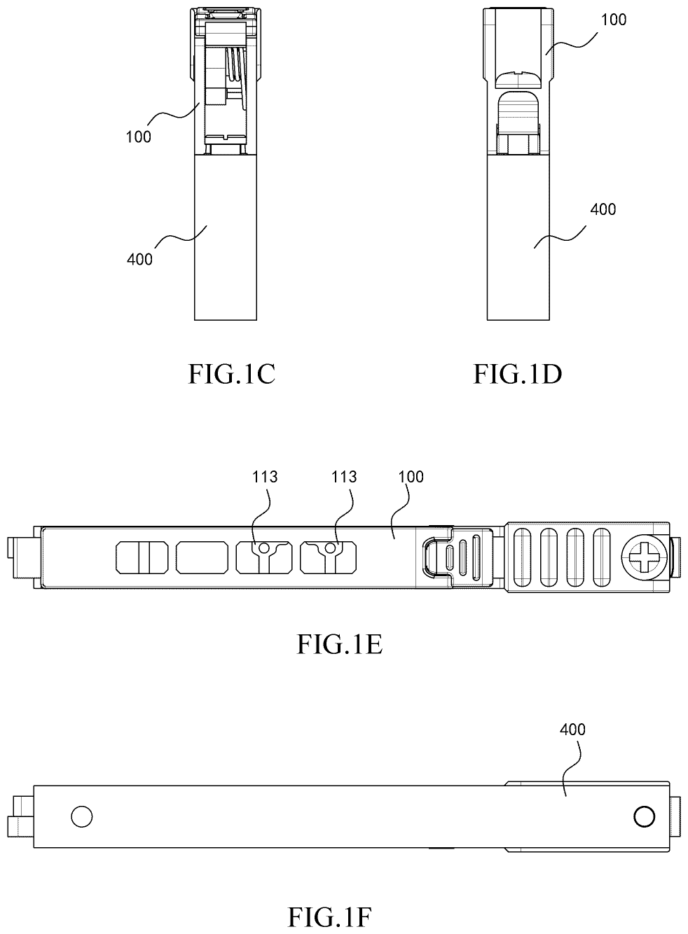

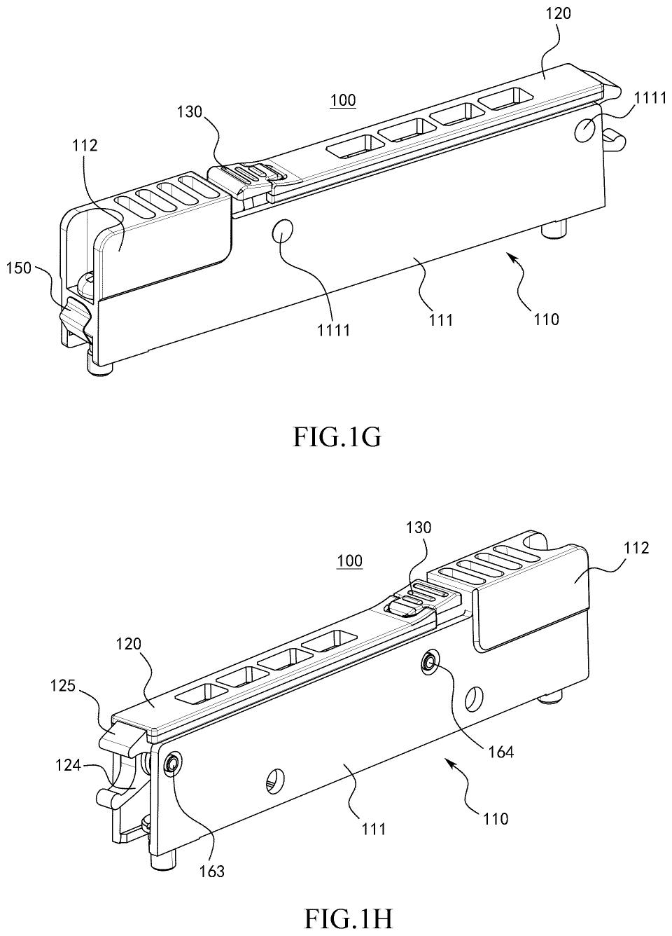

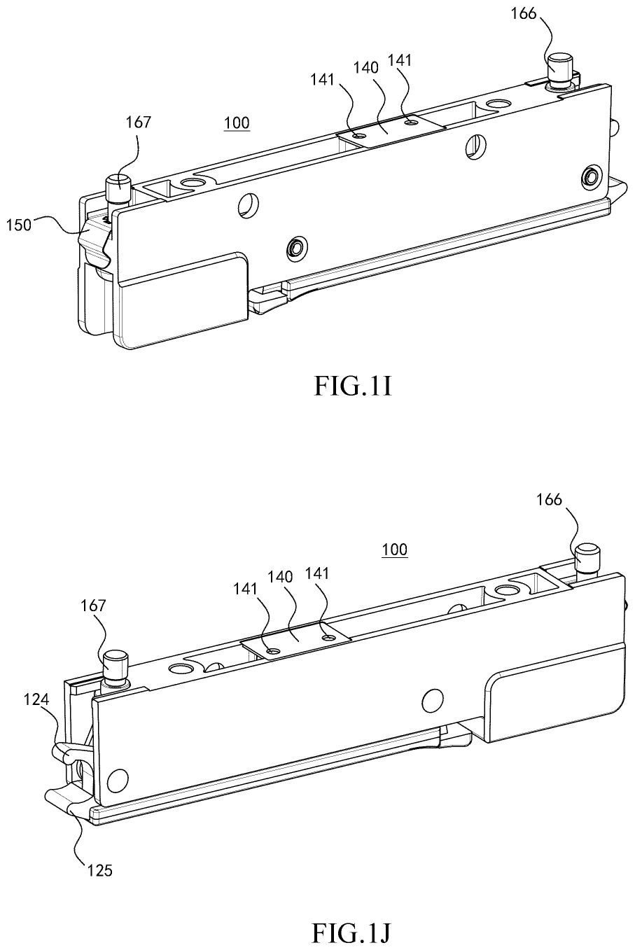

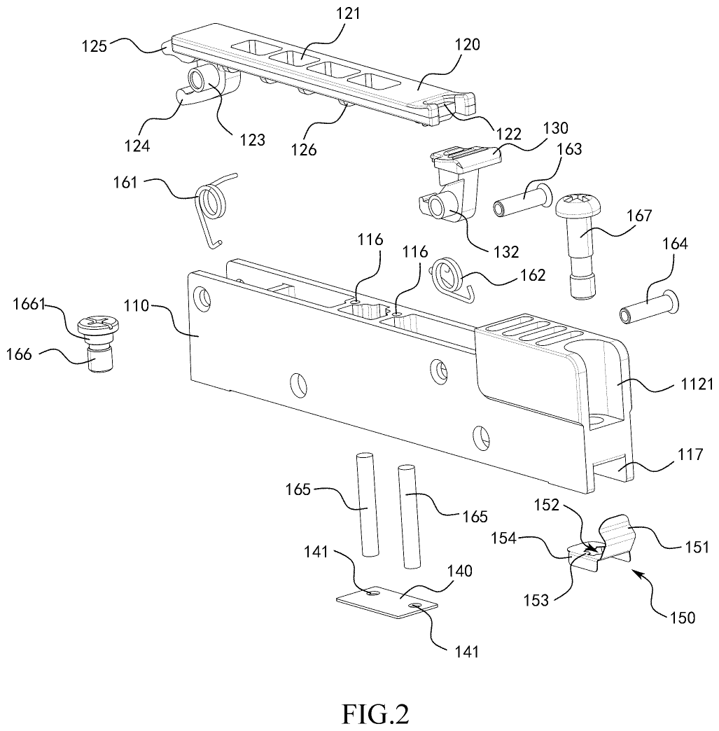

Referring to FIGS. 1A-1J, a first embodiment of an ejector 100 according to the present disclosure is shown as a whole. Referring to FIG. 2, an exploded view of the ejector 100 is shown. As shown, main components of the ejector 100 include a housing 110, a handle 120 and a button 130. In addition, one or more of a cover plate 140, an electromagnetic shielding element 150, a first elastic element 161, a second elastic element 162, a handle shaft 163, a button shaft 164, a light guide element 165, a first fixing element 166 and a second fixing element 167 may be included.

The ejector 100 may be fixed to an object 400. The object 400 may be a server or a storage device of a server, but the present disclosure is not limited thereto. In the present disclosure, a direction in which the ejector 100 and the object 400 are connected to each other (i.e., the up-and-down direction in FIG. 1A) may be called a first direction, but the present disclosure is not limited thereto.

The housing 110 may be fixed to the object 400 by means of the first fixing element 166 and the second fixing element 167. The first fixing element 166 may be one of a screw, a bolt, a rivet and a rivet post. The second fixing element 167 may also be one of a screw, a bolt and a rivet. The first fixing element 166 may be the same as or different from the second fixing element 167.

The housing 110 may have an internal space. The housing 110 may have a pair of side walls 111. A shaft hole 1111 may be formed in the side wall 111. In the embodiment, two shaft holes 1111 may be formed in each side wall 111. A front surface on a side of the housing 110 (i.e., an upper surface in FIG. 1A) may form a head 112. Both the handle 120 and the button 130 may be exposed out of a front surface of the housing 110.

The handle 120 may be generally formed in a plate shape. The handle 120 may include a button engaging portion 122, an insertion abutting portion 124 and a pull-out abutting portion 125. The button engaging portion 122 may be provided at one end of the handle 120, and the insertion abutting portion 124 and the pull-out abutting portion 125 may be provided at the other end of the handle 120. The handle 120 may include a handle shaft installing portion 123 through which the handle shaft 163 may pass, so that the handle 120 may pivot around the handle shaft 163. The handle shaft installing portion 123 may be located at one side close to the insertion abutting portion 124 and the pull-out abutting portion 125. The insertion abutting portion 124 and the pull-out abutting portion 125 may be formed as arms extending from the handle shaft installing portion 123. The insertion abutting portion 124 and the pull-out abutting portion 125 are spaced at a distance to accommodate a rod (not shown) on the bracket between them.

A distance between the button engaging portion 122 and the handle shaft 163 or the handle shaft installing portion 123 is greater than (for example, several times) a distance between the insertion abutting portion 124 and the handle shaft 163 or the handle shaft installing portion 123. The distance between the button engaging portion 122 and the handle shaft 163 or the handle shaft installing portion 123 is greater than (for example, several times) a distance between the pull-out abutting portion 125 and the handle shaft 163 or the handle shaft installing portion 123. In this way, when the handle 120 is actuated on a side close to the button engaging portion 122, an actuating force can be amplified by leverage and transmitted to the insertion abutting portion 124 or the pull-out abutting portion 125.

The handle 120 may form a through hole 121. Specifically, the handle 120 may form a plurality of through holes 121 arranged linearly. The through hole 121 may be formed in a rectangular shape, but the present disclosure is not limited thereto. The through hole 121 may facilitate the observation of the inside of the ejector 100 from the outside, and may facilitate the heat dissipation of the object 400.

A rear side (i.e., a lower side in FIG. 1A) of the handle 120 may be formed with a convex rib 126. Specifically, the handle 120 may have a plurality of convex ribs 126. The plurality of convex ribs 126 may extend in a third direction (i.e., the up-and-down direction in FIG. 1E), and are spaced apart from each other and parallel to each other.

The button engaging portion 122 may be formed in a stepped structure that retreats relative to the front surface of the handle 120.

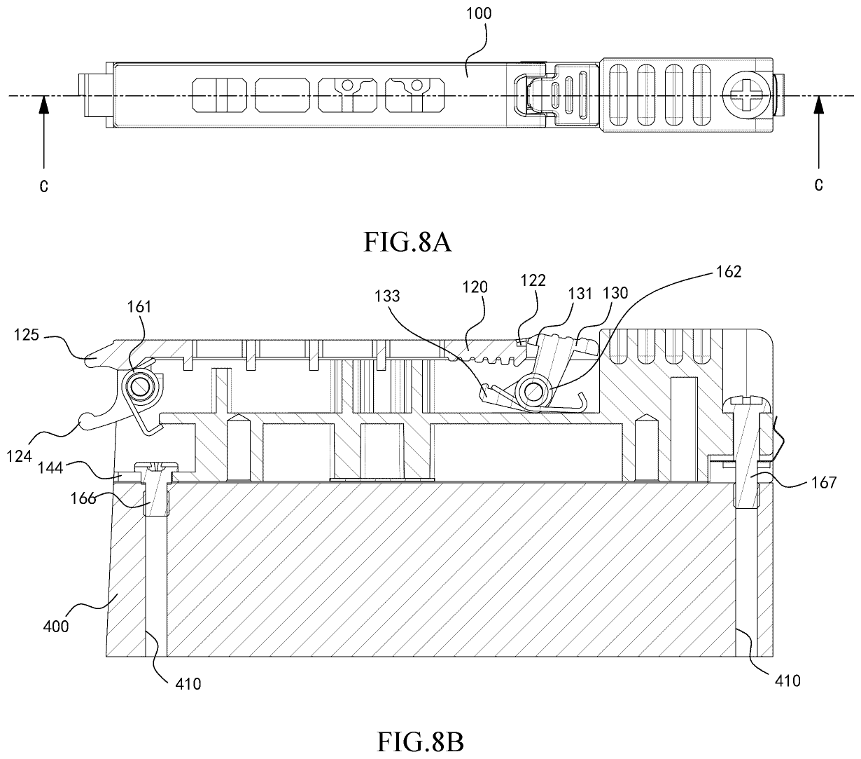

Referring to FIGS. 2 and 8B, the button 130 may include a handle clamping portion 131, a button shaft installing portion 132 and a button elastic element abutting portion 133. The button shaft 164 may pass through the button shaft installing portion 132, so that the button 130 may pivot around the button shaft 164. The button 130 may be pressed to rotate. The button 130 may be provided with an anti-slip portion 134, thereby improving a friction when the button 130 is pressed. The anti-slip portion 134 may be formed as a plurality of strip-shaped protrusions, but the present disclosure is not limited thereto. The handle shaft 163 and the button shaft 164 may be parallel to each other.

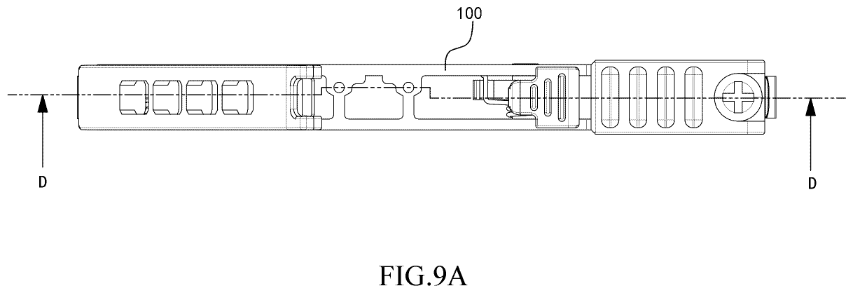

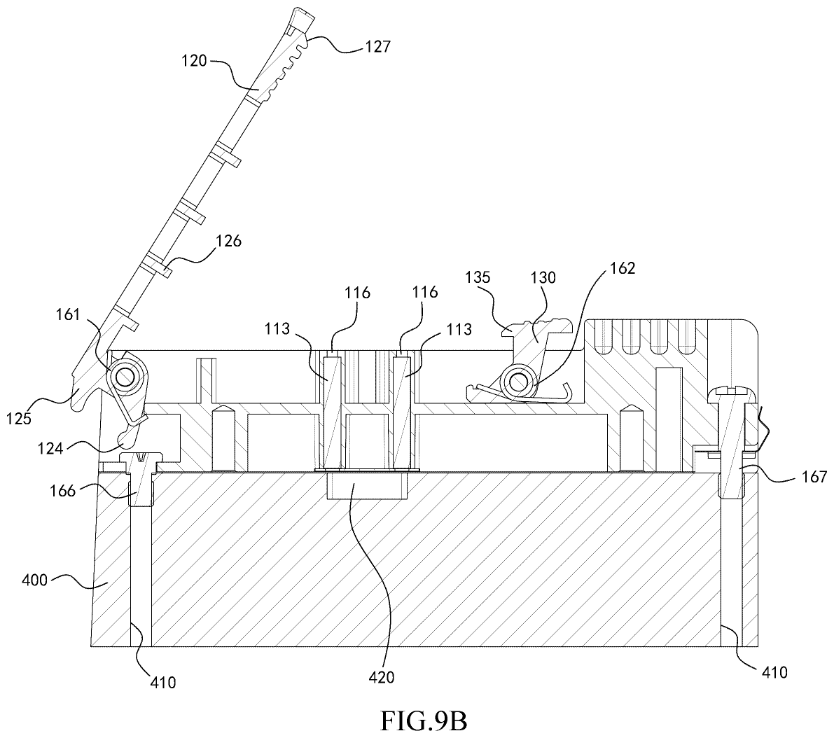

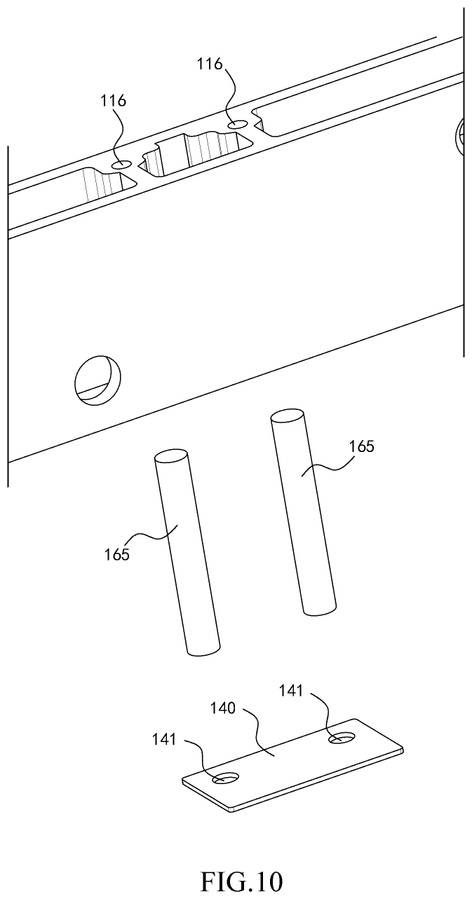

Referring to FIG. 1E, FIG. 2, FIG. 9B and FIG. 10, the ejector 100 may further include a light guide element 165. The light guide element 165 may be used to transmit light emitted by a light emitting portion 420 of the object 400 to the front of the ejector 100 (i.e., an upward side in FIG. 9B). The housing 110 may include a channel 113 extending in the first direction. The light guide element 165 may be provided in the channel 113. The light guide element 165 may be an optical fiber. In the embodiment, the light guide element 165 is straight, so that light may be propagated in a straight line, and a loss of light propagation caused by bending can be avoided. Since the light guide element 165 is straight, the processing of the light guide element 165 and the forming of the channel 113 will be simple.

The ejector 100 may further include a cover plate 140. A front end of the channel 113 (i.e., an upper end shown in FIG. 9B) blocks the light guide element 165. A rear end of the channel (i.e., a lower end shown in FIG. 9B) may be open. The cover plate 140 may cover the open lower end of the channel 113 to block the light guide element 165. In this way, the light guide element 165 may be constrained in the channel 113. The cover plate 140 may be translucent, so as to scatter the light emitted by the object 400 and avoid glare. The cover plate 140 may be formed as a flat plate, thereby being easy to process and shape.

The front end of the channel 113 may have a first hole 116. The cover plate 140 may have a second hole 141. Both the first hole 116 and the second hole 141 are aligned with the light guide element 165. A dimension of the first hole 116 and a dimension of the second hole 141 are smaller than a dimension of of the light guide element 165, so that the light guide element 165 does not move out of the channel 113 through the first hole 116 or the second hole 141.

In the embodiment, the ejector 100 may include two light guide elements 165 and two channels 113. The number of light guide elements 165 may correspond to the number of channels 113. Accordingly, the cover plate 140 may cover two channels 113 and have two second holes 141. It should be noted that the present disclosure does not limit the number of the light guide elements 165 and the number of the channels 113. Since the light guide elements 165 may be arranged in separate channels 113, no additional components are needed to fix or hold the light guide elements 165, so that the number of parts can be reduced.

The ejector 100 may include an electromagnetic shielding element 150. The electromagnetic shielding element 150 contacts the object 400 and the bracket to conduct static electricity between the object 400 and the bracket. The electromagnetic shielding element 150, the object 400 and the bracket may all be made of conductive materials, such as metal. The bracket may be grounded. In this way, the object 400 may be grounded via the electromagnetic shielding element 150 and the bracket. The electromagnetic shielding element 150 may have a function of preventing electromagnetic radiation.

The electromagnetic shielding element 150 may extend outside the housing 110.

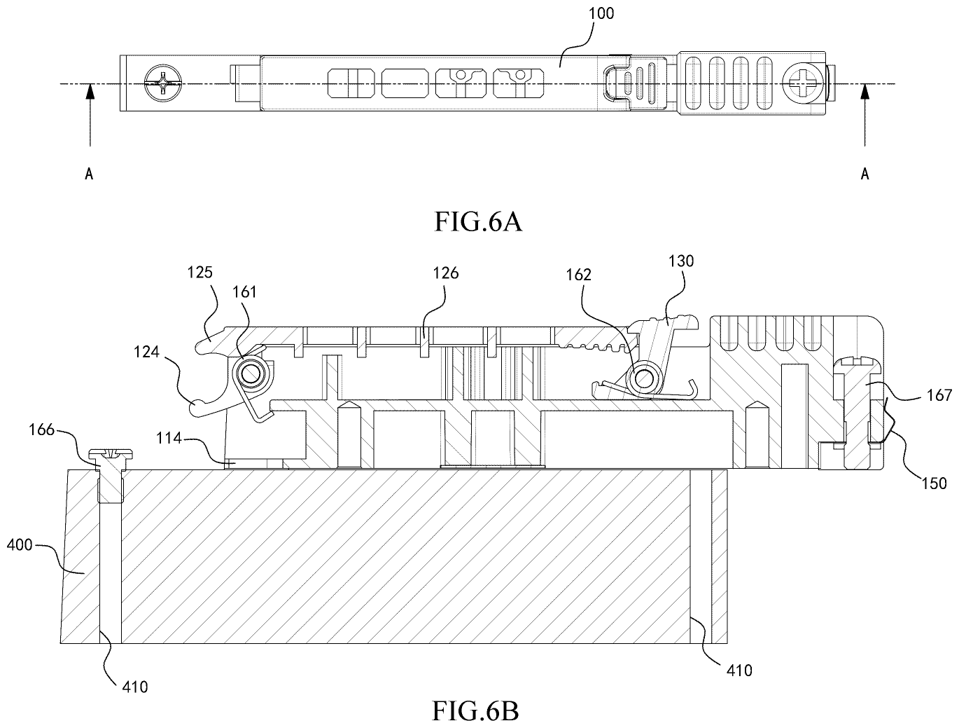

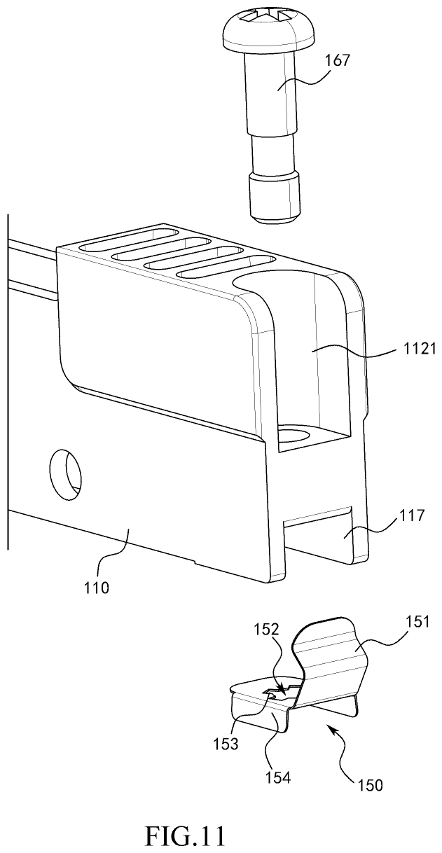

Referring to FIG. 2 and FIG. 11, the electromagnetic shielding element 150 may include a contact arm 151, a contact hole 152 and a wing portion 154. The contact arm 151 may be bent to have elasticity. A plurality of contact protrusions 153 protruding towards a center of the contact hole 152 may be formed in the contact hole 152. The second fixing element 167 may pass through the contact hole 152. In other words, the contact hole 152 may be sleeved on the second fixing element 167. The plurality of contact protrusions 153 may contact the second fixing element 167. The contact arm 151 may be elastically connected to the bracket. Wing portions 154 may extend from both sides of the electromagnetic shielding element 150. The electromagnetic shielding element 150 and the second fixing element 167 may be made of conductive materials. In the embodiment, the electromagnetic shielding element 150 may be disposed at an end of the housing 110, for example, the right end shown in FIG. 6B. In another embodiment, electromagnetic shielding elements 150 may be disposed on both sides of the housing 110, for example, in the third direction, and the electromagnetic shielding element 150 may include a plurality of contact arms 151 that may extend over the entire housing 110 or most of the housing 110 in the second direction.

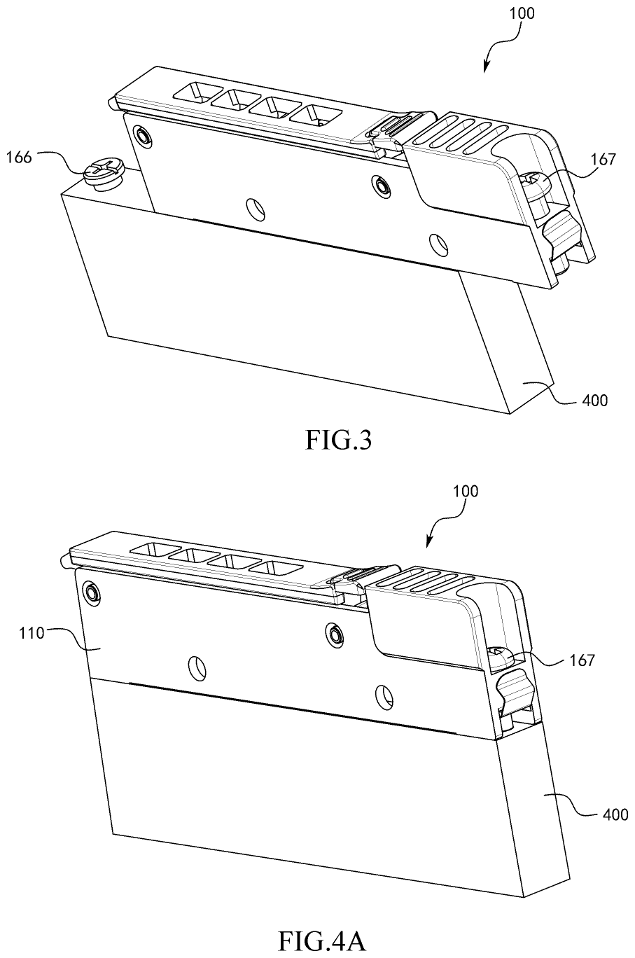

Referring to FIG. 3, FIG. 6A and FIG. 6B, the housing 110 may include a positioning portion 114, and the first fixing element 166 may have a clamped portion 1661. When the ejector 100 is installed on the object 400, the first fixing element 166 is firstly fixed on the object 400 (at this time, the clamped portion 1661 is exposed out of the object 400), and then the ejector 100 slides along the object 400, so that the positioning portion 114 contacts the clamped portion 1661. The positioning portion 114 may be formed as a U-shaped fork. Alternatively, the positioning portion 114 may be formed in a Y-shape or a C-shape. When the ejector 100 slides to align with the object 400, the first fixing element 166 may be engaged with the positioning portion 114 to prevent the housing 110 from moving further relative to the object 400. At this time, the ejector 100 may still move in a direction to the left (the second direction) in FIG. 6B relative to the object 400, but the first fixing element 166 prevents the ejector 100 from moving in the first direction relative to the object 400 because the positioning portion 114 is engaged with the first fixing element 166. After the positioning portion 114 is engaged with the first fixing element 166, the second fixing element 167 may pass through the ejector 100 to fix the ejector 100 to the object 400.

Referring to FIG. 2 and FIG. 11, the housing 110 may have a first concave portion 1121 and a second concave portion 117. The first concave portion 1121 and the second concave portion 117 may be spaced apart in the first direction. The second fixing element 167 may extend from the first concave portion 1121 to the second concave portion 117. That is, the second fixing element 167 may pass through the housing 110. The electromagnetic shielding element 150 may be partially located in the second concave portion 117, and the contact arm 151 of the electromagnetic shielding element 150 extends out of the second concave portion 117. The wing portion 154 may abut against the side wall of the second concave portion 117, so that the electromagnetic shielding element 150 sleeved on the second fixing element 167 remains stable.

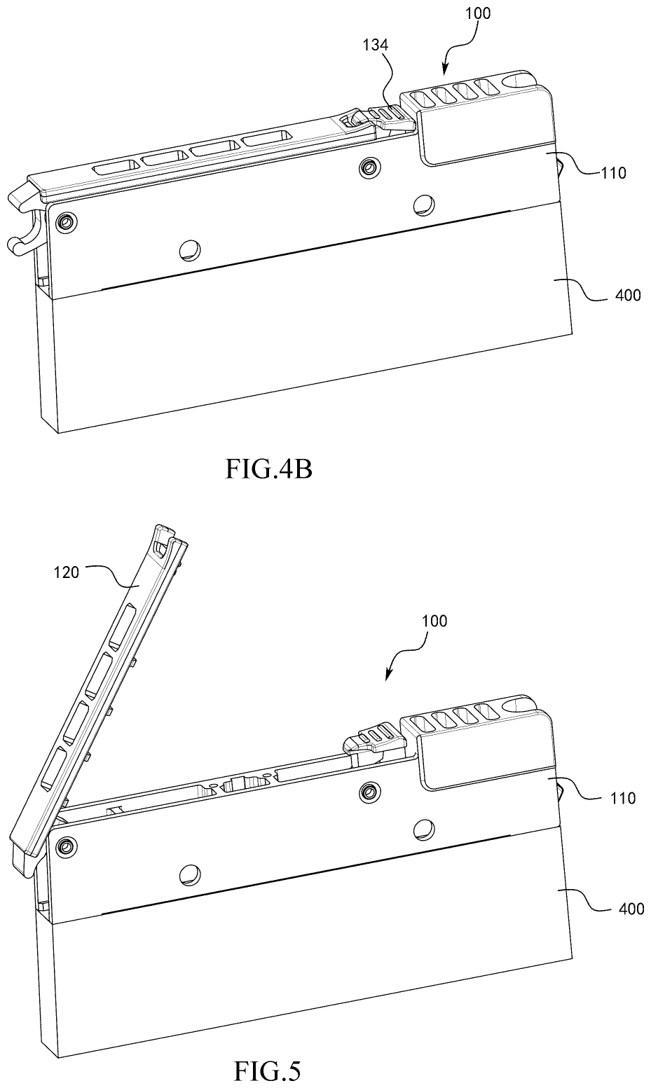

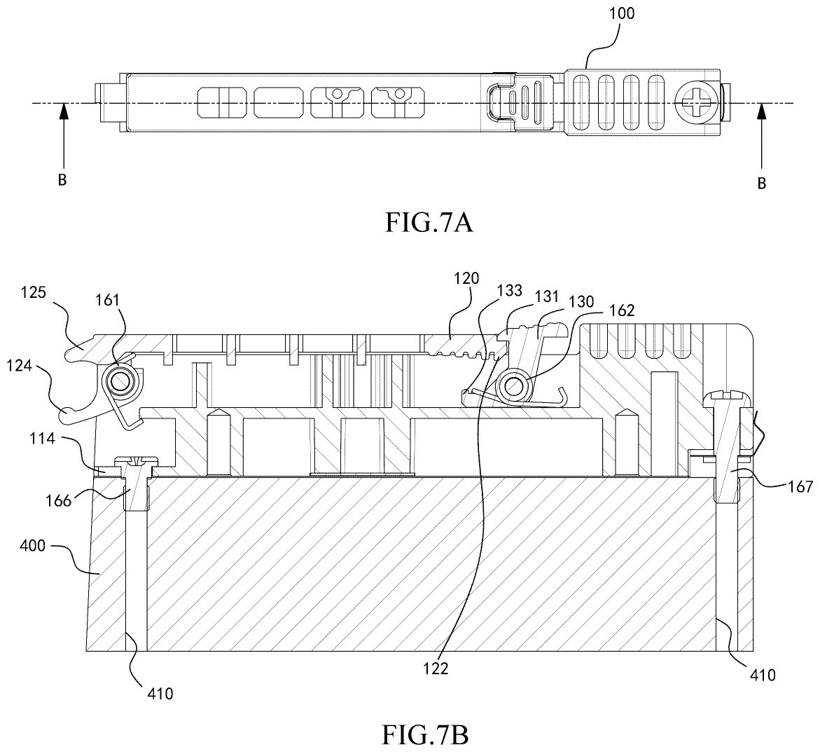

Referring to FIG. 4A, FIG. 4B and FIGS. 7A-8B, a first elastic element 161 may be provided between the housing 110 and the handle 120. The second elastic element 162 may be provided between the housing 110 and the button 130. The first elastic element 161 and/or the second elastic element 162 may be torsion springs, but the present disclosure is not limited thereto. The first elastic element 161 may be sleeved on the handle shaft installing portion 123. The second elastic element 162 may be sleeved on the button shaft installing portion 132. The first elastic element 161 may apply a counterclockwise (i.e., counterclockwise in FIGS. 7B and 8B) force in FIG. 7B to the handle 120. An end of the second elastic element 162 may abut against the button elastic element abutting portion 133 to apply a counterclockwise force in FIG. 7B to the button 130.

When the ejector 100 and the object 400 are inserted into the bracket, the ejector 100 and the object 400 are in a state shown in FIG. 4A, FIG. 7A and FIG. 7B. At this time, the handle 120 is in a first pivot position and the button 130 is in a locking position. When the handle 120 is in the first pivot position and the button 130 is in the locking position, the handle 120 and the button 130 may be substantially flush with the head 112, so that the appearance of the ejector 100 is flat. The handle clamping portion 131 of the button 130 covers the button engaging portion 122 of the handle 120, so that the handle 120 will not bounce up due to the force applied to it by the first elastic element 161.

When the object 400 needs to be pulled out of the bracket, the button 130 may be pressed to change from the state shown in FIG. 7B to a state shown in FIG. 8B, that is, the button 130 is rotated clockwise so that the handle clamping portion 131 no longer blocks the button engaging portion 122 of the handle 120. As shown in FIG. 8B, the button 130 is in an unlocking position at this time.

Referring to FIG. 5, FIG. 9A and FIG. 9B, after pressing the button 130, the first elastic element 161 pushes the handle 120 to rotate counterclockwise (i.e., counterclockwise in FIG. 9B) for a certain angle, and then, an operator may further apply a counterclockwise force to the handle 120 to actuate the handle 120 to a position (the second pivot position) shown in FIGS. 5 and 9B. The button 130 is actuated to an initial position (the locking position) by the second elastic element 162 after releasing the pressing force.

When the handle 120 is rotated counterclockwise, the pull-out abutting portion 125 is also rotated counterclockwise and abuts against the rod on the bracket, thereby pushing the ejector 100 and the object 400 away from the bracket together.

With continued reference to FIG. 5, FIG. 9A and FIG. 9B, contrary to the above process, when it is needed to insert the object 400 into the bracket, the operator rotates the handle 120 clockwise in FIG. 9B. When the handle 120 is rotated clockwise, the insertion abutting portion 124 is also rotated clockwise and abuts against the rod on the bracket, thereby pushing the ejector 100 and the object 400 into the bracket together.

When the handle 120 approaches the button 130, the first inclined plane 127 on the handle 120 cooperates with the second inclined plane 135 on the button 130, so that the button 130 is rotated clockwise against the elastic force of the second elastic element 162 until the handle 120 is rotated to the first pivot position, and the second elastic element 162 pushes the button 130 to rotate counterclockwise to lock the handle 120.

When the handle 120 is in the first pivot position, the first hole 116 may be exposed through the through hole 121 of the handle 120. That is, the light emitted from the light emitting portion 420 of the object 400 is scattered by the cover plate 140, transmitted by the light guide element 165 through the second hole 141 on the cover plate 140, and emitted to the front of the ejector 100 through the first hole 116 on the housing 110 and the through hole 121 of the handle 120.

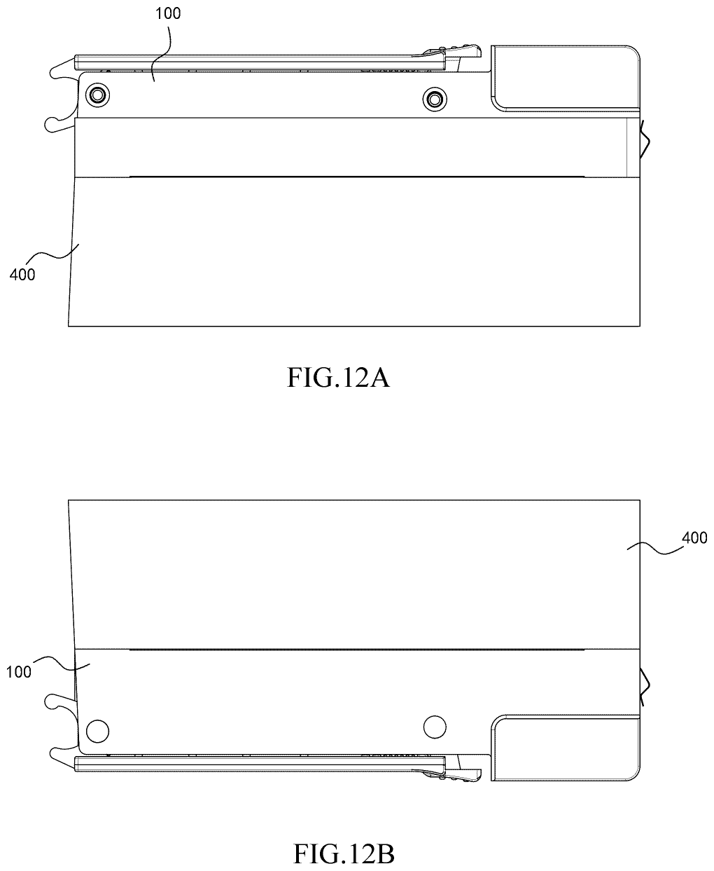

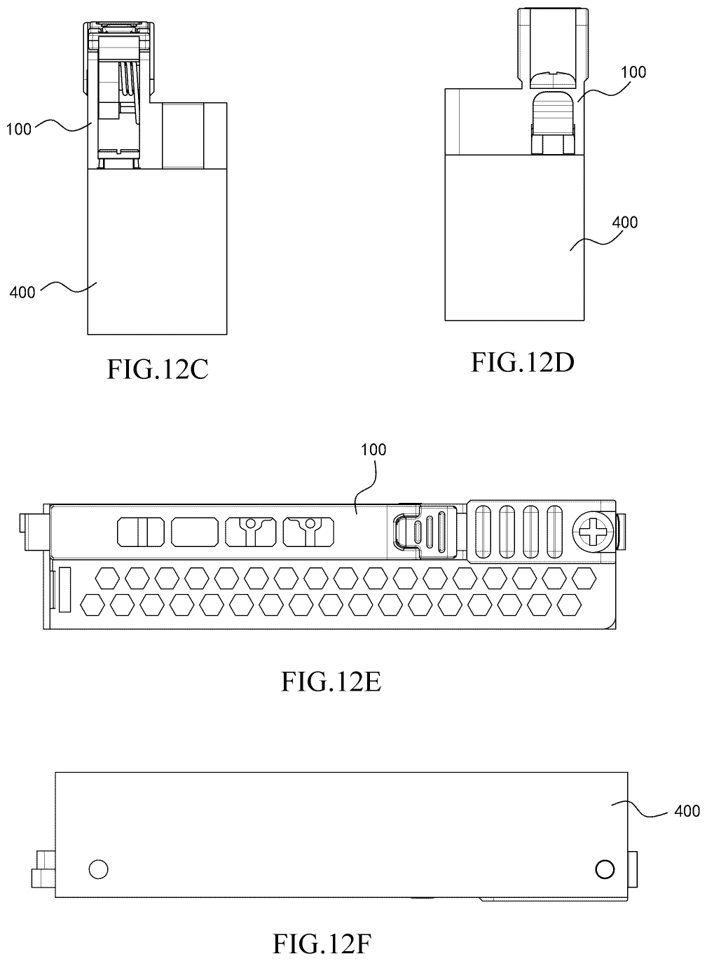

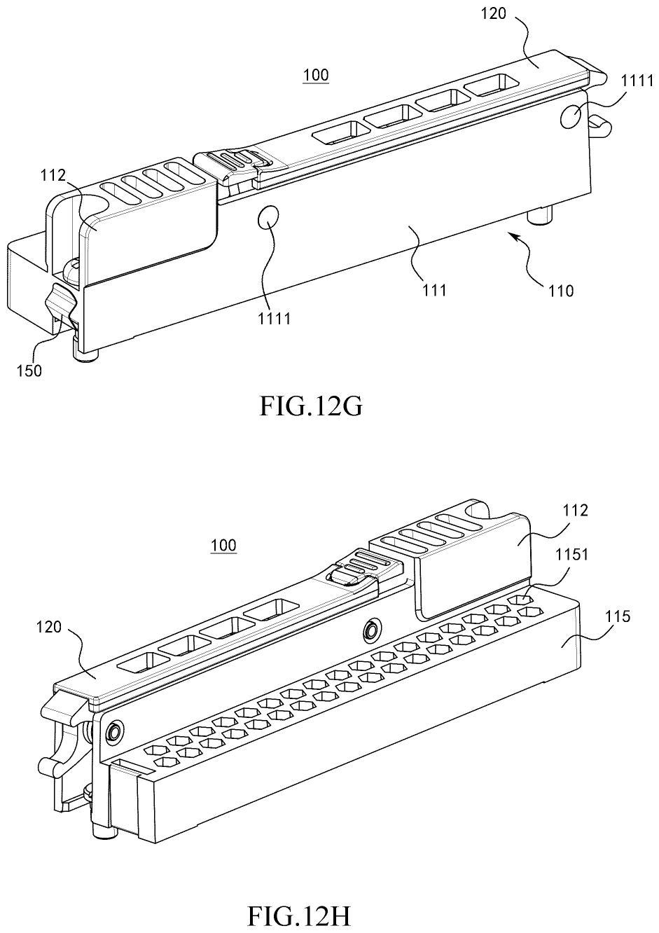

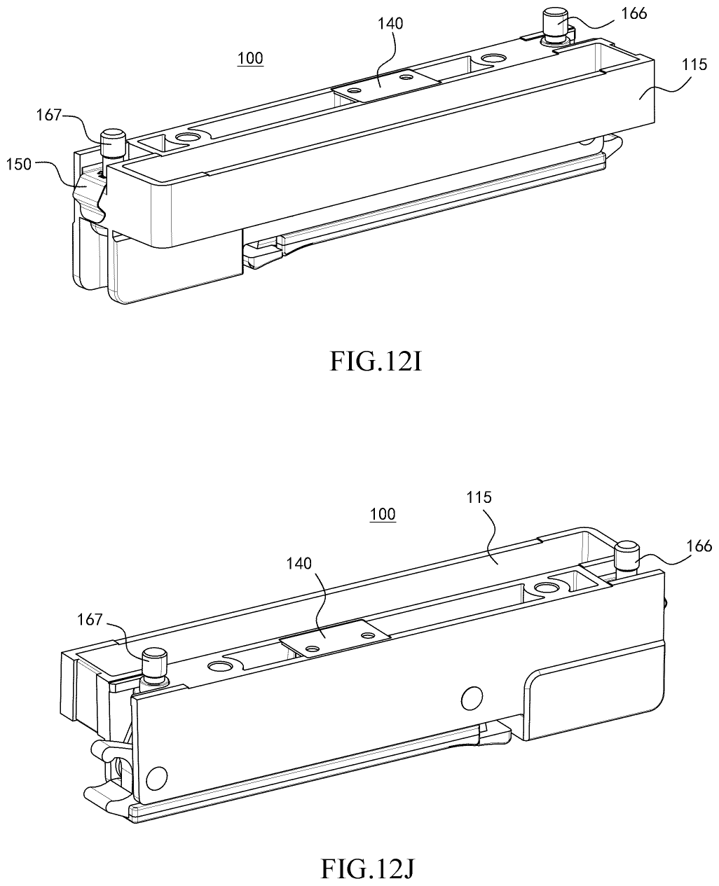

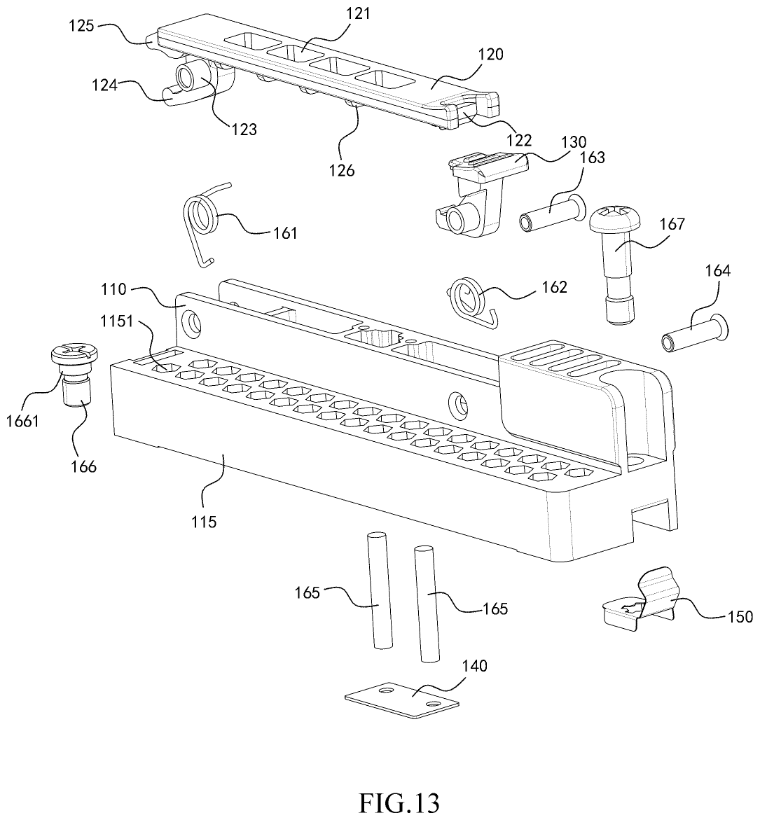

FIGS. 12A to 13 show a second embodiment of the present disclosure. The second embodiment of the present disclosure will be described below, in which the same parts of the second embodiment as those of the first embodiment will be omitted to avoid repetition.

Referring to FIGS. 12A to 13, the ejector 100 may include an extension portion 115. The extension portion 115 may be integrally formed with the housing 110 and extend laterally from the housing 110. Alternatively, the extension portion 115 may be formed separately from the housing 110 and fixed together. The front surface of the extension portion 115 (a surface shown in FIG. 12E) may have a plurality of holes arranged in a plurality of arrays. These holes may provide better heat dissipation effect for the object 400. These holes may be one or more of regular hexagon, circle, rectangle and triangle. The ejector 100 of the embodiment may be applied to an object 400 with a larger size.

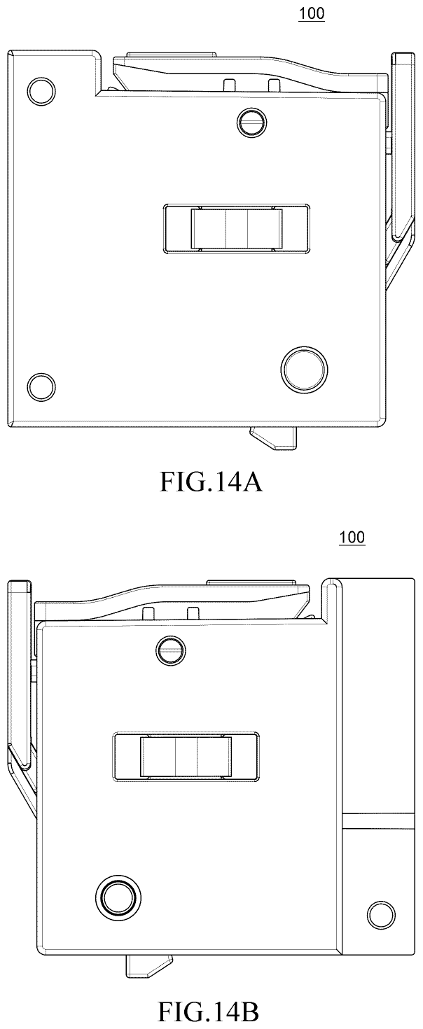

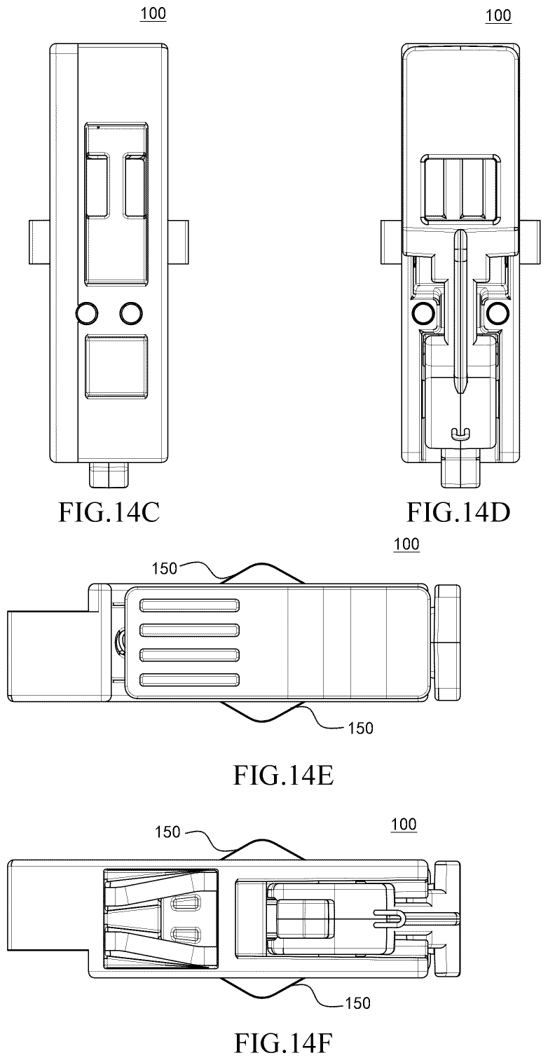

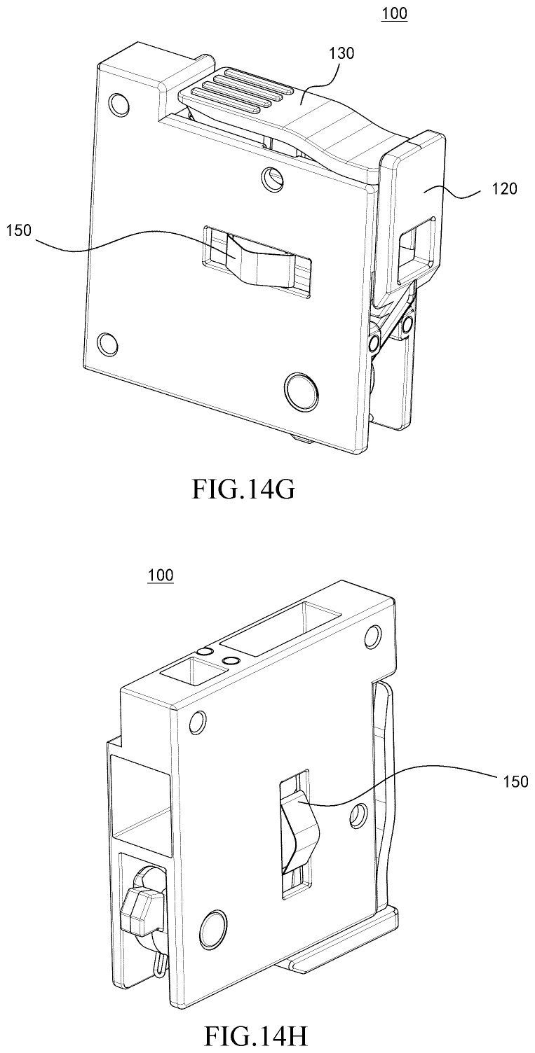

FIGS. 14A to 17C show a third embodiment of the present disclosure. The third embodiment of the present disclosure will be described below, in which the same parts of the third embodiment as those of the first embodiment will be omitted to avoid repetition.

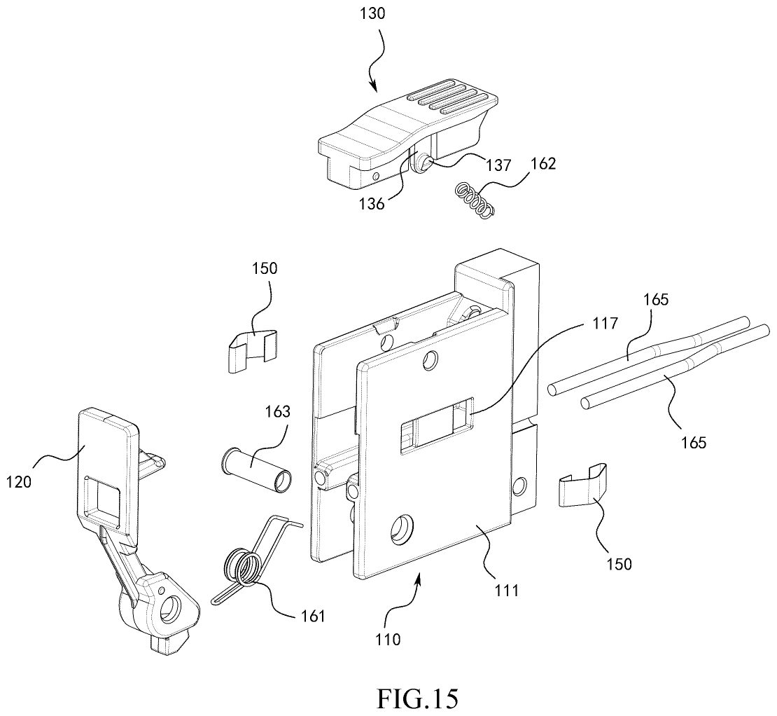

Referring to FIGS. 14A to 15, electromagnetic shielding elements 150 may be located at both sides of the housing. The electromagnetic shielding element 150 may have an approximately isosceles triangle shape. The handle 120 may be exposed on the front surface of the housing 110 (i.e., a right side in FIG. 14A), and the button may be exposed on an upper surface of the housing 110 (i.e., an upper side in FIG. 14A). In the embodiment, the handle 120 may have a bent shape.

Each of both sides of the button 130 may have an elastic arm 136 and a pivot portion 137 provided at an end of the elastic arm, respectively. The pivot portion 137 may protrude outward from the elastic arm 136. Pivot portions 137 on both sides of the button 130 may be respectively provided in corresponding holes on both sides of the housing 110, so that the button 130 may be pivotally connected to the housing 110. In the embodiment, the button 130 may be pivotally connected to the housing 110 due to the elastic arms 136 and the pivot portions 137, without an additional pivot, thereby reducing the number of parts.

In the embodiment, the second elastic element 162 may be a coil spring, and both ends of the second elastic element 162 respectively abut against the button 130 and a corresponding inclined plane inside the housing 110.

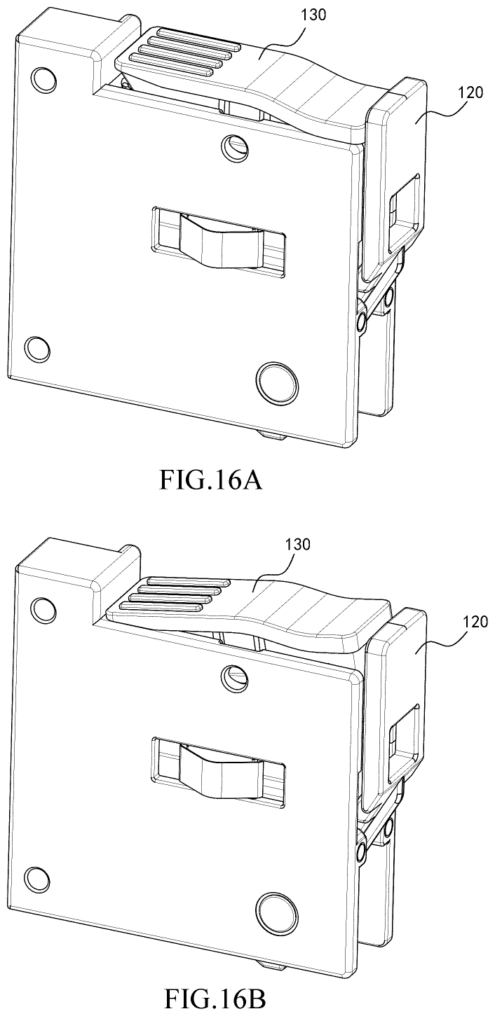

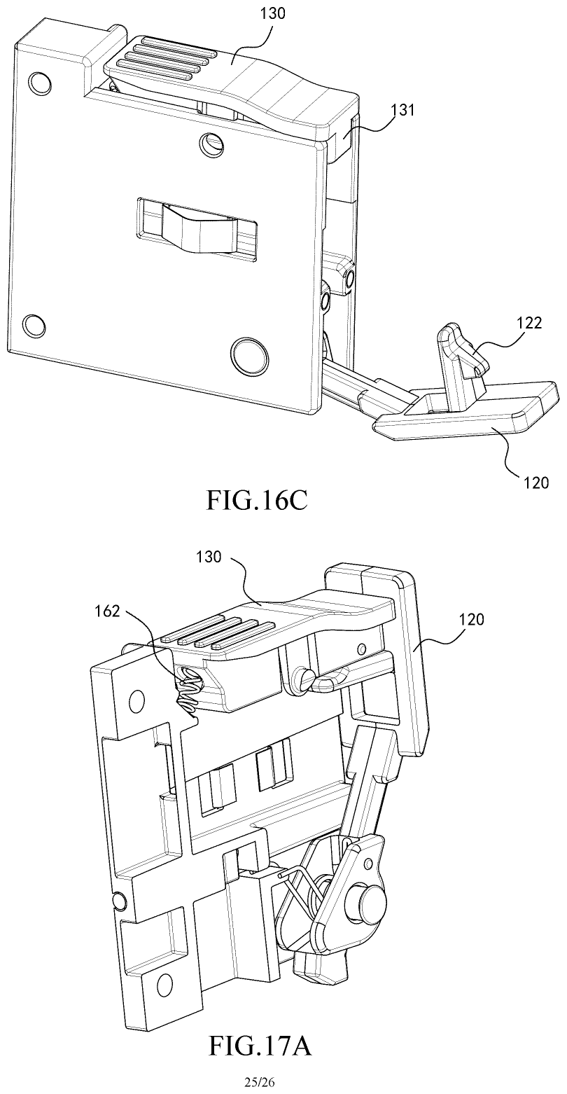

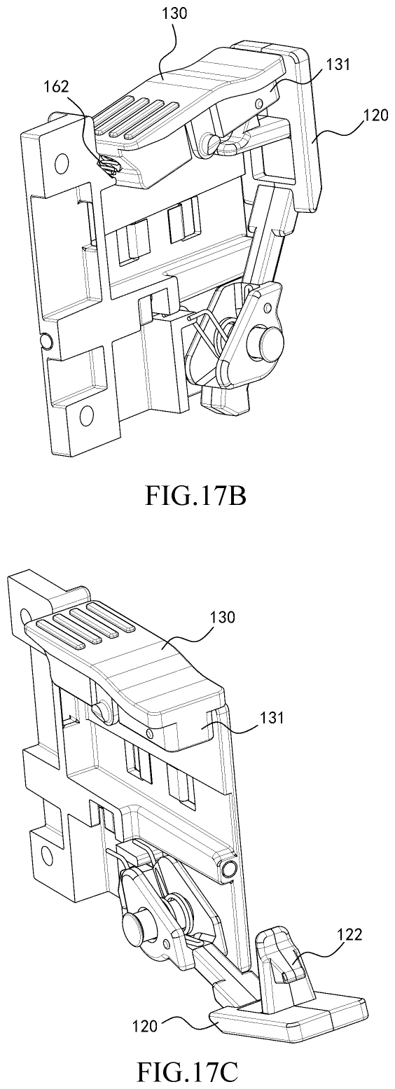

Referring to FIGS. 16A to 17C, the handle 120 may have a hook-shaped button engaging portion 122. The button 130 may have a handle clamping portion 131 in cooperation with the hook-shaped button engaging portion 122.

Those skilled in the art will easily think of other embodiments of the present disclosure after considering the specification and practicing the present disclosure as mentioned above. The present disclosure is intended to cover any variations, uses or adaptations of the present disclosure, which follow the general principles of the present disclosure and include common knowledge or common technical means in the technical field that are not disclosed in the present disclosure. Also, the specification and its embodiments are to be regarded as examples only, and the scope and spirit of the present disclosure are indicated by the claims of the present disclosure.

Although the present disclosure has been described with reference to the examples of typical embodiments, the terms used are illustrative and exemplary, rather than restrictive. Since the present disclosure may be embodied in various forms without departing from the spirit and essence of the present disclosure, it should be understood that the above-mentioned embodiments are not limited to any of the foregoing details, but should be interpreted in the broadest sense within the scope defined by the claims, so all changes that fall within the scope of the claims or their equivalents should be covered by the claims.

What is claimed is:

1. An ejector, fixed to an object, wherein the ejector comprises:
a housing, fixed to the object by means of a first fixing element and a second fixing element;
a handle, pivotally connected to the housing around a first pivot axis and having a first pivot position and a second pivot position; and
a button, pivotally connected to the housing around a second pivot axis and having a locking position and an unlocking position, wherein the handle is locked by the button when the button is in the locking position and the handle is in the first pivot position,
wherein the first fixing element prevents the housing from moving in a first direction relative to the object and allows the housing to move in a second direction relative to the object, and the second fixing element prevents the housing from moving in the first direction and the second direction relative to the object.

2. The ejector according to claim 1, wherein the first direction is perpendicular to the second direction.

3. The ejector according to claim 1, wherein the housing comprises a positioning portion formed as a U-shaped fork, wherein any one of the first fixing element and the second fixing element is one of a screw, a bolt, a rivet and a rivet post, and the first fixing element is engaged with the positioning portion to prevent the housing from moving in the first direction relative to the object.

4. The ejector according to claim 1, wherein the handle comprises a button engaging portion, an insertion abutting portion and a pull-out abutting portion, wherein the button locks the handle by abutting against the button engaging portion, a distance from the button engaging portion to the first pivot axis is greater than a distance from the insertion abutting portion to the first pivot axis, and the distance from the button engaging portion to the first pivot axis is greater than a distance from the pull-out abutting portion to the first pivot axis.

5. The ejector according to claim 4, wherein the ejector is installed to a bracket, wherein when the handle is rotated from the first pivot position to the second pivot position, the pull-out abutting portion abuts against a part of the bracket to at least partially pull out the object from the bracket, and when the handle is rotated from the second pivot position to the first pivot position, the insertion abutting portion abuts against the part of the bracket to fix the object to the bracket.

6. The ejector according to claim 5, wherein the ejector comprises a first elastic element and a second elastic element, wherein the first elastic element is provided between the housing and the handle to apply a force towards the second pivot position to the handle, and the second elastic element is provided between the housing and the button to apply a force towards the locking position to the button.

7. The ejector according to claim 1, wherein the ejector further comprises a light guide element, and the housing comprises a channel extending along the first direction, wherein the light guide element is provided in the channel.

8. The ejector according to claim 7, wherein the ejector further comprises a cover plate, wherein one end of the channel blocks the light guide element, the other end of the channel is open, and the cover plate covers the other end that is open of the channel to block the light guide element.

9. The ejector according to claim 8, wherein the one end of the channel has a first hole, and the cover plate has a second hole, wherein both the first hole and the second hole are aligned with the light guide element, and each of a size of the first hole and a size of the second hole is smaller than a size of the light guide element.

10. The ejector according to claim 8, wherein the light guide element is an optical fiber, the optical fiber is straight, and the cover plate is translucent.

11. The ejector according to claim 9, wherein the handle has a through hole, and the first hole is exposed through the through hole when the handle is in the first pivot position.

12. The ejector according to claim 5, wherein the ejector comprises an electromagnetic shielding element, and the electromagnetic shielding element contacts the object and the bracket and extends out of the housing.

13. The ejector according to claim 12, wherein the electromagnetic shielding element has a contact arm, and the contact arm is elastically connected to the bracket.

14. The ejector according to claim 12, wherein the electromagnetic shielding element has a contact hole, and a plurality of contact protrusions extending to a center of the contact hole are formed in the contact hole, wherein the second fixing element passes through the contact hole, and the plurality of contact protrusions contact the second fixing element.

15. The ejector according to claim 12, wherein the housing has a first concave portion and a second concave portion, wherein the second fixing element extends from the first concave portion to the second concave portion, and the electromagnetic shielding element is partially located in the second concave portion.

16. The ejector according to claim 13, wherein the electromagnetic shielding element is located at both sides of the housing.

17. The ejector according to claim 16, wherein the electromagnetic shielding element has a plurality of contact arms extending along the second direction.

18. The ejector according to claim 1, wherein the ejector comprises an extension portion, wherein the extension portion is integrally formed with the housing and extends laterally from the housing, and a front surface of the extension portion has a plurality of holes arranged in a plurality of arrays.

19. The ejector according to claim 1, wherein the handle has a convex rib, wherein the convex rib protrudes towards the housing in the first direction and extends in a third direction, and the third direction is perpendicular to the first direction and the second direction.

20. The ejector according to claim 6, wherein the handle has a first inclined plane and the button has a second inclined plane, and the first inclined plane abuts against the second inclined plane to push the button from the locking position to the unlocking position during a rotation of the handle from the second pivot position to the first pivot position.
